(19) United States
(12) Patent Application Publication
(10) Pub. No.: US 2026/0189208 A1
(43) Pub. Date: Jul. 2, 2026

(54) DUAL-STAGE RADIO FREQUENCY TRANSFORMERS

(71) Applicant: Skyworks Solutions, Inc., Irvine, CA (US)

(72) Inventor: Seunghwan Yoon, Irvine, CA (US)

(21) Appl. No.: 19/433,578

(22) Filed: Dec. 26, 2025

Related U.S. Application Data
(60) Provisional application No. 63/739,453, filed on Dec. 27, 2024.
(60) Provisional application No. 63/739,456, filed on Dec. 27, 2024.

(51) Int. Cl. H03H 7/42; H03F 3/45; H04B 1/04

(52) U.S. Cl. CPC H03H 7/425; H03F 3/45475; H04B 1/04; H03F 2200/451; H04B 2001/0408

(57) ABSTRACT

Aspects of this disclosure relate to multi-stage balanced-to-unbalanced transformers with enhanced input impedance symmetry between positive and negative input terminals resulting in improved common mode rejection and stable supply voltage provided to a source of the differential signal fed to the positive and negative input terminals. A multi-stage balanced-to-unbalanced transformer includes a balance-to-balance transformer connected in series with a balanced-to-unbalanced transformer.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

Embodiments of this disclosure relate to balanced-to-unbalanced transformers.

### Description of Related Technology

Radio frequency (RF) communication systems can be used for transmitting and/or receiving signals of a wide range of frequencies.

For example, an RF communication system can be used to wirelessly communicate RF signals in a frequency range from about 30 kHz to about 300 GHz, such as in the range of about 410 megahertz (MHz) to about 7.125 gigahertz (GHz) for Fifth Generation (5G) cellular communications in Frequency Range 1 (FR1).

RF communication systems can include without limitation mobile phones, tablets, base stations, network access points, customer-premises equipment (CPE), laptops, and wearable electronics.

In certain applications, RF communications systems a balanced circuit may be interfaced with an unbalanced circuit. In these and other systems, a balanced-to-unbalanced (balun) transformer may be used to transform the differential signal provided by the balanced circuit to a single ended signal received by the unbalanced circuit without disturbing the impedance of either circuit.

### SUMMARY

According to one embodiment there is provided a multi-stage transformer including: a balanced-balanced (balbal) transformer including a pair of input terminals configured to receive an input differential signal, and a pair of intermediate output terminals configured to output an intermediate differential signal; and a balanced-unbalanced (balun) transformer including a pair of intermediate input terminals connected to the pair of intermediate output terminals and configured to receive the intermediate differential signal from the balanced-balanced transformer, and a pair of output terminals configured to output a single ended signal.

In one example, the balanced-balanced transformer includes a biasing terminal connected to a DC voltage source and the balanced-balanced transformer is configured to provide the DC voltage to a balanced circuit.

In one example, the balanced-balanced transformer includes an input conductive line and the biasing terminal is connected to a center tap of the input conductive line.

In one example, output impedance of the balanced-balanced transformer is matched to input impedance of the balanced-unbalanced transformer.

In one example, the input terminals are connected to a pair of signal terminals of the balanced circuit, and the pair of signal terminals are configured to provide the input differential signal to the balanced-balanced transformer and receive the DC voltage, via the pair of input terminals.

In one example, the balanced circuit includes a differential amplifier.

In one example, the input differential signal and the intermediate differential signal are in phase.

In one example, the intermediate differential signal and the single ended signal are in phase.

In one example, the output terminals are unbalanced.

In one example, the intermediate output terminals are balanced.

In one example, a first output terminal of the pair of output terminals is connected to a device and a second output terminal of the pair of output terminals is connected to electric ground.

In some aspects, the techniques described herein relate to a radio frequency front end including the multi-stage transformer wherein the device includes an antenna, and the input terminals are connected to an amplifier of the radio frequency front end.

In one example, the transformer ratio of the balanced-balanced transformer is 1:1.

In one example, the ratio of the balanced-unbalanced transformer is 1:1.

In one example, the transformer ratio of the balanced-unbalanced transformer is 1:N, where N is an integer larger than 1.

In one example, the balanced-balanced transformer includes a first primary coil connected between the pair of input terminals and a first secondary coil connected to the pair of intermediate output terminals, wherein the first primary coil is magnetically coupled to the first secondary coil.

In one example, transformer ratio of the balanced-balanced transformer is 1:1.

In one example, the first primary coil includes a center tap connected to a voltage source.

In one example, the balanced-unbalanced transformer includes a second primary coil connected between the pair of intermediate output terminals and a second secondary coil connected to the pair of output terminals, wherein the second primary coil is magnetically coupled to the second secondary coil.

In one example, transformer ratio of the balanced-unbalanced transformer is 1:1.

In one example, transformer ratio of the balanced-unbalanced transformer is different than one 1:1.

In one example, transformer ratio of the balanced-unbalanced transformer is 1:N, where N is an integer larger than 1.

In one example, the second primary coil includes a center tap connected to electrical ground.

In one example, the balanced-unbalanced transformer includes a lattice transformer fabricated over a first substrate.

In one example, the lattice transformer includes: a first inductor connected between a first intermediate input terminal of the pair of intermediate input terminals and a first output terminal of the pair of output terminals; a first inductor connected between a second intermediate input terminal of the pair of intermediate input terminals and a second output terminal of the pair of output terminals; a first capacitor connected between the first intermediate input terminal and electric ground; and a second capacitor connected between the second intermediate input terminal the first output terminal.

In one example, the lattice transformer includes a lumped element circuit.

In one example, the balanced-balanced transformer includes a first primary coil connected between the pair of input terminals and a first secondary coil connected to the pair of intermediate output terminals, wherein the first primary coil is magnetically coupled to the first secondary coil.

In one example, transformer ratio of the balanced-balanced transformer is 1:1.

In one example, transformer ratio of the balanced-unbalanced transformer is 1:1.

In one example, transformer ratio of the balanced-unbalanced transformer is 1:N, where N is an integer larger than 1.

In one example, the first primary coil includes a center tap connected to a voltage source.

In one example, the balanced-balanced transformer includes a multilayer structure including a first planar conductive line connecting the pair of intermediate output terminals and a second planar conductive line connecting the pair of input terminals, wherein the second conductive line is electromagnetically coupled to the first conductive line and is vertically separated from the first conductive line by a dielectric layer.

In one example, the balanced-balanced transformer is formed over the first substrate.

In one example, the balanced-balanced transformer is formed over the first substrate.

In one example, the balanced-balanced transformer is formed over a second substrate separate from the first substrate.

In one example, at least a portion of the first planar conductive line is substantially parallel to a portion of the second planar conductive line.

In one example, an area bounded by the first conductive line includes a rectangular or square shape.

In one example, a radio frequency module is provided, the radio frequency including: a differential power amplifier configured to provide an amplified output signal; the multi-stage transformer of any one of the previous examples and aspects, the multi-stage transformer arranged to receive the amplified output signal on the pair of input terminals of the multi-stage transformer.

In one example, a mobile device is provided, the mobile device including: a differential power amplifier configured to provide an amplified output signal; the multi-stage transformer of any one of the previous examples, the multi-stage transformer arranged to receive the amplified output signal on the pair of input terminals of the multi-stage transformer; and an antenna arranged to receive the single ended signal and to wirelessly transmit the single ended signal.

According to another embodiment there is provided a multi-stage transformer including: a closed-conductive-loop including a first planar conductive line and a second planar conductive line connected to and vertically separated from the first planar conductive line; an input planar conductive line vertically separated from the first planar conductive line and connecting to a pair of input terminals configured to receive an input differential signal; an output planar conductive line vertically separated from the second planar conductive line and connecting to a pair of output terminals configured to output a single ended signal, the first planar conductive line electromagnetically coupled to the input planar conductive line and the second planar conducive line electromagnetically coupled to the output planar conductive line, the closed-conductive-loop configured to couple the input planar conductive line to the output conductive line.

In one example, the first and second planar conductive lines connected via a at least a first pair of conductive vias to form the closed-conductive-loop, the multi-stage transformer further including a third planar conductive line vertically separated from the first planar conductive line and the input planar conductive line, the third planar conductive line connected to the first planar conductive line by a second pair of conductive vias and in parallel with the first planar conductive line, wherein the third planar conductive line is electromagnetically coupled to the input planar conductive line.

In one example, the first and second planar conductive lines connected via a at least a first pair of conductive vias to form the closed-conductive-loop, the multi-stage transformer further including a fourth planar conductive line vertically separated from the second planar conductive line and the output planar conductive line, the fourth planar conductive line connected to the first pair of conductive vias by a third pair of conducive vias in parallel with the first planar conductive line, wherein the fourth planar conductive line is electromagnetically coupled to the output planar conductive line.

In one example, the input planar conductive line is formed below the first planar conductive line and above the third planar conductive line.

In one example, the output planar conductive line is formed below the second planar conductive line and above the fourth planar conductive line.

In one example, at least a portion of the input planar conductive line is parallel to a portion of the first planar conductive line and a portion of the third planar conductive line.

In one example, at least a portion of the output planar conductive line is parallel to a portion of the second planar conductive line and a portion of the fourth planar conductive line.

In one example, projections of a first area bound by the first planar conductive line and a third area bound by the third planar conductive line on a plane of the input planar conductive line at least partially overlap with an input area bound by the input planar conductive line.

In one example, projections of a second area bound by the second planar conductive line and a fourth area bound by the fourth planar conductive line on a plane of the output planar conductive line at least partially overlap with an output area bound by the output planar conductive line.

In one example, first, third, and input areas include triangular shapes.

In one example, second, fourth, and output areas include triangular shapes.

In one example, at least a portion of the input planar conductive line is perpendicular to a portion of the output planar conductive line.

In one example, the multi-stage transformer including further includes a biasing terminal connected between the input planar conductive line and a DC voltage source.

In one example, the input terminals are connected to a pair of signal terminals of a balanced circuit, wherein the signal terminals are configured to provide the input differential signal to the input planar conductive line and receive the DC voltage, via the pair of input terminals.

In one example, the balanced circuit includes a differential amplifier.

In one example, the input differential signal and the single ended signal are in phase.

In one example, the output terminals are unbalanced.

In one example, the input terminals are balanced.

In one example, a first output terminal of the pair of output terminals is connected to device and a second output terminal of the pair of output terminals is connected to electric ground.

In one example, there is provided a radio frequency front end, the radio frequency front end including: a differential power amplifier configured to provide an amplified output signal; the multi-stage transformer of any one of the previous examples, the multi-stage transformer arranged to receive the amplified output signal on the pair of input terminals.

In one example, there is provided a mobile device, the mobile device including: a differential power amplifier configured to provide an amplified output signal; the multi-stage transformer of any one of the previous examples, the multi-stage transformer arranged to receive the amplified output signal on the pair of input terminals; and an antenna arranged to receive and wirelessly transmit the single ended signal.

According to another embodiment there is provided a radio frequency front end including: a balanced circuit configured to generate a differential signal; an antenna configured to receive a single ended signal; and a multi-stage transformer including: a balanced-balanced (balbal) transformer including: a pair of input terminals configured to receive the differential signal, and a pair of intermediate output terminals configured to output an intermediate differential signal; and a balanced-unbalanced (balun) transformer including: a pair of intermediate input terminals connected to the pair of intermediate output terminals and configured to receive the intermediate differential signal from the balanced-balanced transformer, and a pair of output terminals configured to output the single ended signal.

In one example, the balanced-balanced transformer includes a biasing terminal connected to a DC voltage source and balanced-balanced transformer is configured to provide the DC voltage to the balanced circuit.

In one example, the balanced-balanced transformer includes an input conductive line and the biasing terminal is connected to a center tap of the input conductive line.

In one example, the input terminals are connected to a pair of signal terminals of the balanced circuit, wherein the signal terminals are configured to provide the differential signal to the balanced-balanced transformer and receive the DC voltage, via the pair of input terminals.

In one example, the balanced circuit includes a differential amplifier.

In one example, the differential signal and the intermediate differential signal are in phase.

In one example, the intermediate differential signal and the single ended signal are in phase.

In one example, the output terminals are unbalanced.

In one example, the intermediate output terminals are balanced.

In one example, a first output terminal of the pair of output terminals is connected to the antenna and a second output terminal of the pair of output terminals is connected to electric ground.

In one example, the transformer ratio of the balanced-balanced transformer is 1:1.

In one example, the transformer ratio of the balanced-unbalanced transformer is 1:1.

In one example, the transformer ratio of the balanced-unbalanced transformer is 1:N, where N is an integer larger than 1.

### BRIEF DESCRIPTION OF THE DRAWINGS

Embodiments of this disclosure will now be described, by way of non-limiting example, with reference to the accompanying drawings.

FIG. 1 is a schematic diagram of one example of a communication network.

FIG. 2A is a schematic diagram of one example of a communication link that uses carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3 is a schematic diagram of an RF system comprising a balanced circuit connected to an unbalanced circuit by a balanced-to-unbalanced (balun) transformer.

FIG. 4A illustrates a schematic diagram of an RF system comprising a balun transformer configured to connect a balanced circuit to an unbalanced circuit and provide a supply voltage to the balanced circuit.

FIG. 4B is a schematic diagram of an example balun transformer circuit that can be used in the RF system shown in FIG. 4A.

FIG. 5A is a schematic diagram of a (balanced-to-balanced) balbal transformer configured to provide supply voltage received via a center tap to a device connected to its input terminals.

FIG. 5B is a schematic diagram of a balun transformer having a grounded center tap.

FIG. 5C is a schematic diagram of an RF system comprising an multi-stage balanced-to-unbalanced transformer formed having balanced input terminals and unbalanced output terminals and configured to provide supply voltage to a device connected to its input terminals.

FIG. 6A illustrates is a schematic diagram illustrating an example multi-stage balun configuration (top panel), which can be used to implement a planar multi-stage balun comprising balbal and balun transformers having transformer ratios of 1:1, and the corresponding inductor-based equivalent circuit (bottom panel).

FIG. 6B illustrates is a schematic diagram illustrating another example multi-stage balun configuration (top panel), which can be used to implement a planar multi-stage balun comprising balbal and balun transformers having transformer ratios of 1:1 and 1:2, respectively, and the corresponding inductor-based equivalent circuit (bottom panel).

FIG. 7A illustrates is a schematic diagram illustrating another example multi-stage balun configuration, which can be implemented as a planar multi-stage balun transformer having a transformer ratio 1.

FIG. 7B illustrates is a schematic diagram illustrating another example multi-stage balun configuration, which can be implemented as a planar multi-stage balun transformer having a transformer ratio 2.

FIG. 8A illustrates a schematic diagram of an example multi-stage balun transformer comprising a modified balbal transformer connected to a modified balun transformer.

FIGS. 8B-8C is a schematic diagram illustrating a three-dimensional (3D) view of a planar multi-stage balun transformer formed based on the equivalent circuit shown in FIG. 8A. In FIG. 8C the vertical distances between conductive lines is exaggerated to illustrate the individual transmission lines and the conductive vias connecting the conductive lines.

FIG. 8D illustrates a side cross-sectional view of the planar multi-stage balun transformer shown in FIGS. 8B-8C.

FIG. 8E illustrates top views of the conductive lines that are stacked and electrically connected to form the planar multi-stage balun transformer shown in FIGS. 8B-8D.

FIG. 9A illustrates the equivalent circuit of an example RF system that uses the planar multi-stage balun transformer shown in FIGS. 8A-8C to connect a balanced portion of the RF system to an unbalanced portion of the RF system.

FIGS. 9B-9E illustrate the spectrum of the return losses (B), insertion losses (C), phase difference between output signals (D), and common mode rejection ratio (CMRR) for the equivalent circuit shown in FIG. 9A.

FIG. 10A is a schematic diagram of an RF system comprising a multi-stage balanced-to-unbalanced transformer comprising a lattice balun configured to provide supply voltage to a device connected to its input terminals.

FIGS. 10B-10D illustrate the spectrum of the return losses (B), insertion losses (C), phase difference between output signals (D), for the multi-stage balanced-to-unbalanced transformer shown in FIG. 10A.

FIGS. 11A-11B illustrate top view (A) and 3D view (B) of an example implementation of the multi-stage balanced-to-unbalanced transformer shown in FIG. 10A.

FIG. 12 illustrates an example of a mobile device.

### DETAILED DESCRIPTION OF CERTAIN EMBODIMENTS

### Overview

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IOT), Vehicle-to-Everything (V2X), and High-Power User Equipment (HPUE).

3GPP introduced Phase 1 of fifth generation (5G) technology in Release 15, and is currently in the process of developing Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

### Communication Network

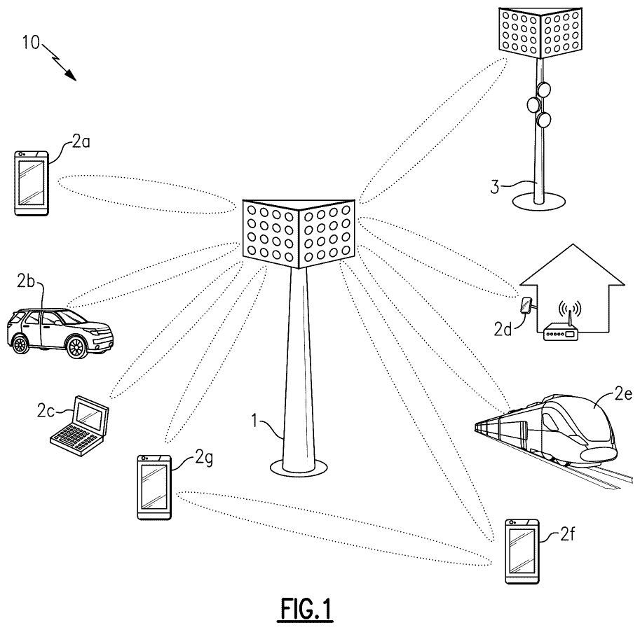

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local region network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

A peak data rate of a communication link (for instance, between a base station and a user device) depends on a variety of factors. For example, peak data rate can be affected by channel bandwidth, modulation order, a number of component carriers, and/or a number of antennas used for communications.

For instance, in certain implementations, a data rate of a communication link can be about equal to M*B*log₂(1+S/N), where M is the number of communication channels, B is the channel bandwidth, and S/N is the signal-to-noise ratio (SNR).

Accordingly, data rate of a communication link can be increased by increasing the number of communication channels (for instance, transmitting and receiving using multiple antennas), using wider bandwidth (for instance, by aggregating carriers), and/or improving SNR (for instance, by increasing transmit power and/or improving receiver sensitivity).

5G NR communication systems can employ a wide variety of techniques for enhancing data rate and/or communication performance.

### Carrier Aggregation

Improvement on network data rates was possible under the 3GPP LTE-Advanced by introducing the concept of carrier aggregation (CA). Under CA, a user equipment (UE) is simultaneously linked to more than one channel and thereby more resource blocks (RBs) are assigned to a single user. While CA applied to the downlink (DL-CA) bands enhances data transfer from the network to the UE, CA on the uplink (UL-CA) bands improves data transfer from the UE to the network. Typically, DL data traffic is often higher than the UL traffic; therefore, implementations of CA have focused on DL-CA.

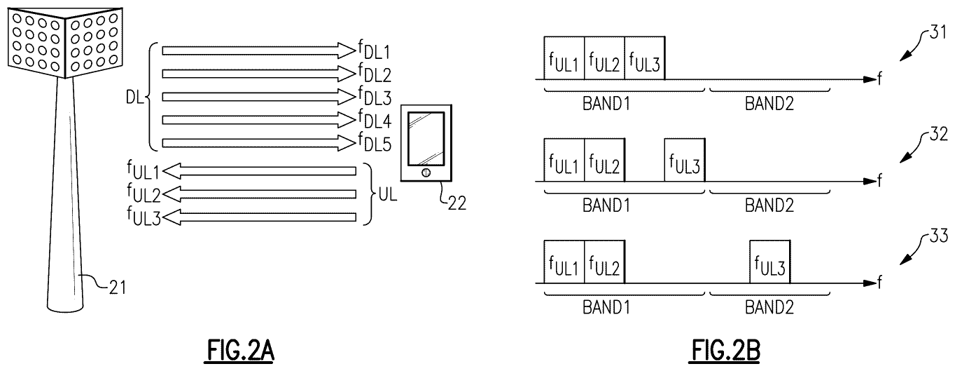

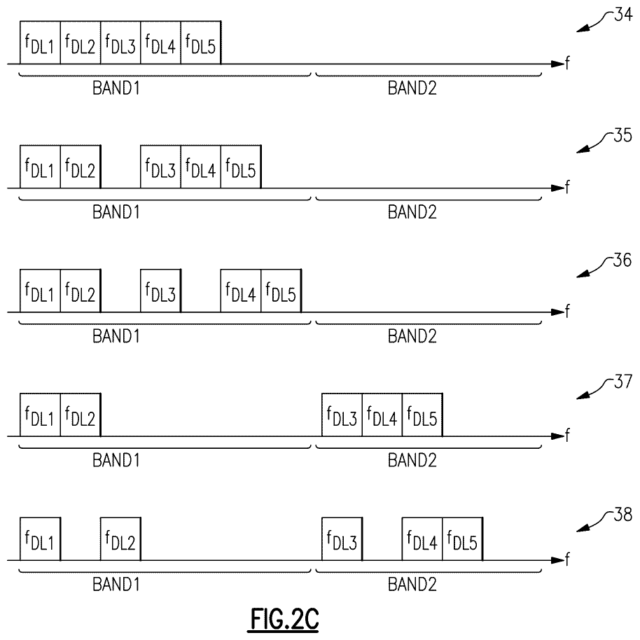

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations. Carrier aggregation can present challenges for designing bandpass filters with high out-of-band rejection to isolate the frequency carriers. Filters disclosed herein can be implemented to support carrier aggregation applications.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage regions, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as Wi-Fi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid Wi-Fi users and/or to coexist with Wi-Fi users. Enhanced license assisted access (eLAA) refers to an evolution of LAA that aggregates licensed and unlicensed spectrum for both downlink and uplink.

### Application of Balun Transfer in Wireless Systems

In various stages of a wireless system a balanced circuit that generates a differential signal may be interfaced to an unbalanced circuit configured to receive a single ended signal. In some such embodiments, the output impedance of the balanced circuit and the input impedance of the unbalanced circuit can be different. In some embodiments, a balanced-to-unbalanced (balun), also referred to as balanced-unbalanced transformer, may be configured to transform the differential signal to the single ended signal. In some such embodiments, the balun transformer may be further configured to have an input impedance matched with the output impedance of the balanced circuit and an output impedance matched to the unbalanced circuit. In various RF and microwave systems, e.g., antenna systems, differential signaling, and test equipment where signal integrity is important, baluns may be used to match different impedance levels and eliminate common-mode noise. In some cases, the balanced circuit may include signal paths with symmetry with respect to a reference voltage (e.g., ground voltage). In some cases, the balanced circuit may generate a differential signal comprising positive and negative signal portions output via output terminals having identical or near identical impedances with respect to the reference voltage. In some examples, the amplitude and phase of the positive and negative signal portions may be configured to allow common noise cancelation. As such it is desirable for the balun transformer to preserve the phase and amplitude of a received differential signal while generating the single ended signal. Various multi-stage balun transformers disclosed herein may provide a smooth transition from a balanced circuit or device to an unbalanced circuit device and provide a stable supply voltage to the balanced circuit, while reducing or eliminating perturbance of the balanced circuit and perturbance of the differential signal. In some implementations, disclosed multi-stage balun transformers can be used in a wireless system, e.g., for connecting the front-end system to the antenna system.

FIG. 3 is a schematic diagram of an RF system comprising a balanced circuit 302, an unbalanced circuit 310, a balun transformer 306 connecting the balanced circuit 302 to the unbalanced circuit 310. In some embodiments, the balanced circuit/device 302 may be connected to the balun transformer 306 by a first transmission line 304 (e.g., a balanced planar transmission line such as a coplanar stripline) and the balun transformer 306 may be connected to the unbalanced circuit/device 310 by a second transmission line 308 (e.g., a unbalanced planar transmission line or a coaxial line). In some examples, the balanced circuit 302 may have an output impedance Zₒᵤₜ₁ different from an input impedance Zᵢₙ₂ of the unbalanced circuit 310. In some such examples, the balun transformer 306 may have an input impedance Zᵢₙ₁ substantially equal to Zₒᵤₜ₁ and an output impedance Zₒᵤₜ₂ substantially equal to Zᵢₙ₂. In some examples, the balun transformer 306 may be configured to transform a differential signal received from the balanced circuit 302 via the balanced transmission line 304 to a single ended signal and provide the single ended signal to the unbalanced circuit 310 via the unbalanced transmission line 308. In some examples, the unbalanced circuit 310 may comprise a first terminal (herein referred to as signal output terminal) connected to an antenna 311 and a second terminal (herein reference output terminal) connected to a reference voltage 312 (e.g., electrical ground). In some such examples, the balanced circuit 302 may comprise a differential amplifier and the balun transformer 306 may configured to receive an amplified differential signal from the differential amplifier and provide an amplified single ended signal to the antenna 311 for free space radiation and wireless transmission.

While embodiments may be discussed with reference to balun transformers used in wireless systems, the disclosed balun transformers and any suitable principles and advantages of these balun transformers disclosed herein can be used in other systems.

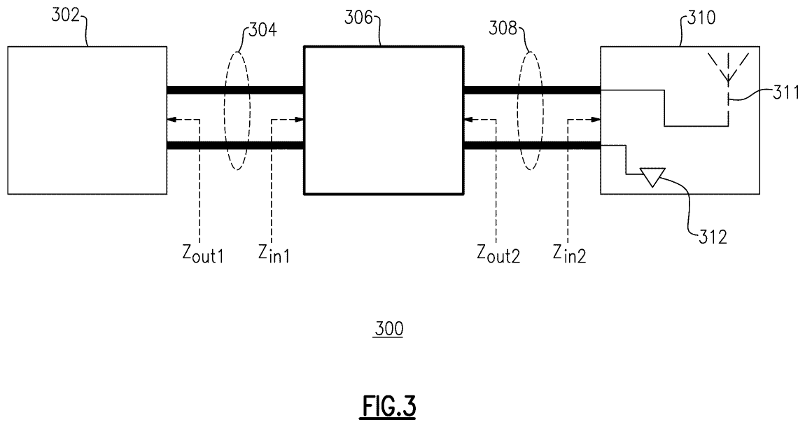

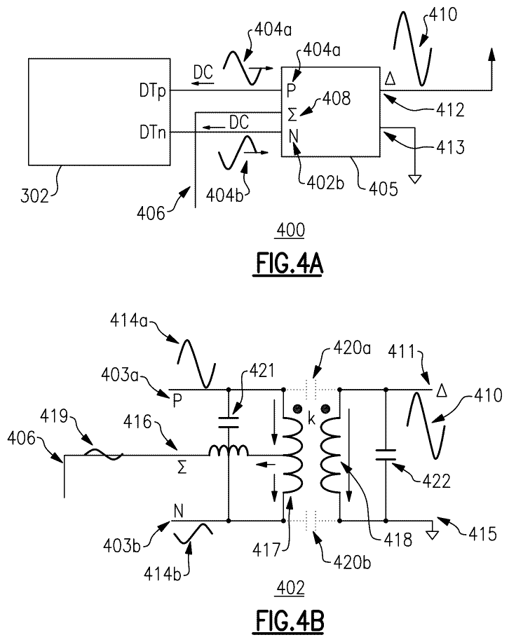

FIG. 4A illustrates a schematic diagram of an RF system 400 comprising a balanced-to-unbalanced (balun) transformer 405 configured to connect a balanced circuit 302 to an unbalanced circuit (not shown) and provide a supply voltage to the balanced circuit 302 via the output terminals DTp, DTn of the balanced circuit 302. In some embodiments, the balanced circuit 302 (e.g., a differential amplifier) may output a differential signal comprising a positive signal portion 404a output from the positive output terminal DTp and a negative signal portion 404b output from the negative output terminal DTn that can be 180 degrees out of phase with respect to the positive signal portion 404b. In some embodiments, the balun transformer 405 may comprise a positive input terminal 402a (P) configured to receive the positive signal portion 404a, a negative input terminal 402b (N) configured to receive the negative signal portion 404b, a signal output terminal 412 (Δ) configured to output a single ended signal 410 with respect to a reference output terminal 413, which may be connected to electrical ground. In some cases, the single ended signal 410 may have an amplitude substantially equal to the sum of the amplitudes of the positive and negative signal portions 404a, 404b. In some embodiments, the balun transformer 405 may comprise a supply voltage terminal 408 (Σ) configured to receive a DC supply voltage (e.g., from DC voltage source) via a DC line 406, and provide the received voltage to the balanced circuit 302 via the positive and negative output terminals DTp, DTn and the positive and negative input terminals 402a, 402b.

In some examples, the balun transformer 405 can be an ideal (e.g., symmetric) balun transformer that provides substantially identical input impedances for the positive and negative signal portions 404a, 404b. In some such examples, the positive and negative signal portions 404a, 404b, may have substantially equal magnitudes resulting in complete or near complete cancellation of common noise and substantially zero AC signal component on the DC line 406.

In some embodiments, e.g., in a practical implementation, the positive and negative input terminals of a balun transformer (e.g., a non-ideal or asymmetric balun transformer) may have different input impedances. FIG. 4B is a schematic diagram of an example single-stage inductor-based balun transformer 402 that may be used to connect the balanced circuit 302 to an unbalanced circuit. In some examples, single-stage inductor-based balun transformer 402 can be a non-ideal balun transformer having input terminals with different input impedances. In some cases, the balun transformer 402 may comprise a primary coil 417 connecting a positive input terminal 403a to a negative input terminal 403b, magnetically coupled to a secondary coil 418 connecting a signal output terminal 411 to a reference output terminal 415 single positive input terminal 403a to a negative input terminal 403b. Additionally, in some cases, the primary and secondary coils 417, 418, can be capacitively coupled by parasitic capacitors 420a, 420b. In some embodiments, the winding of the primary and secondary coils 417, 418, may be configured such that a secondary signal generated between two ends of the secondary coil by a primary signal applied between the two ends of the primary coil is substantially in phase with the primary signal. In some embodiments, the balun transformed 402 may include first and second capacitors 421, 422, connect in parallel with the primary coil 417 and secondary coil 418, respectively. In some embodiments, the supply voltage terminal 416 of the balun transformer 402 may comprise a center tap of the primary coil 417. In various implementations, the turn ratio (also referred to as the transformer ratio) of the primary and secondary coils 417, 418, can be 1/N, 1, or N/1, where N is a positive integer. In some such implementations, the turn ratio of the primary and secondary coils 417, 418, may be determined based on the output impedance of the balanced circuit and/or transmission line that provide the differential signal to the balun transformer 402 and the input impedance of the unbalanced circuit and/or transmission line receives the single ended signal from the balun transformer 402.

In some embodiments, the impedance of the positive input terminal 403a can be different from the impedance of the negative input terminal 403b resulting an imbalance between the positive and negative signal portions 414a, 414b. In some such embodiments, the amplitudes of the positive and negative signal portions 414a, 414b provided to the balun transformer 402 by a balanced circuit (e.g., balanced circuit 302) can be different. As a result, the common noise may not be cancelled, and a residual AC signal 419 component may be generated on the DC line 406. In some examples, the residual AC signal 419 may be transmitted to the balanced circuit 302 and disturb and degrade its performance.

Advantageously, the disclosed multi-stage balun transformers (described below) may provide substantially identical electromagnetic paths and input impedances for the positive and negative signal portions, and thereby allow transition from a near-ideal differential signal comprising positive and negative signal portions having substantially equal amplitudes to a single ended signal. In some cases, common noise cancellation between the positive and negative signal portions may allow the disclosed multi-stage balun transformers to output a low noise single ended signal and provide a stable DC supply voltage, which is substantially free of parasitic AC components, or has highly reduced parasitic AC components, to the balanced circuit from which the differential signal is received.

### Multi-Stage Balanced-to-Unbalanced Transformers

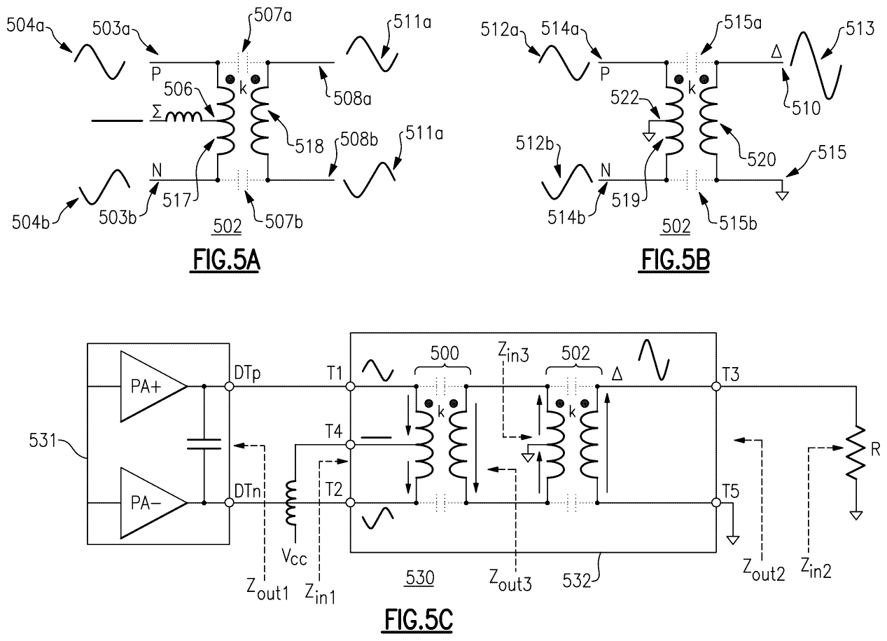

In some embodiments, a multi-stage balanced-to-unbalanced (balun) transformer may comprise a two-stage transformer comprising a balanced-to-balanced (balbal) transformer and a balun transformer where the output terminals of the balbal transformer are connected to the input terminals of the balun transformer, the differential signal may be provided to the input terminals of the balbal transformer, and the single ended signal may be output via the output terminals of the balun transformer. In some cases, the balbal transformer may be configured to provide a supply voltage to a device or circuit that generates the differential signal via the input terminals of the balbal and output terminals of the device. FIGS. 5A and 5B schematically illustrate example balbal and balun transformers, respectively, which may be connected to form a multi-stage balun transformer.

FIG. 5A is a schematic diagram of a balanced-to-balanced (balbal), also referred to as balanced-balanced, transformer 500, that can be an inductive transformer comprising a primary coil 517 connecting a first positive input terminal 503a to a first negative input terminal 503b, and a secondary coil connecting a positive output terminal 508a to a negative output terminal 508b, where the primary coil 517 is magnetically coupled to the secondary coil 518. Additionally, in some cases, the primary and secondary coils 517, 518, can be capacitively coupled by parasitic capacitors 507a, 507b. In some embodiments, the primary coil 517 may be configured to receive an input differential signal comprising positive and negative input signal portions 504a, 504b, via the positive and negative input terminals 503a, 503b, respectively, and the secondary coil 518 may be configured to output an output differential signal comprising positive and negative output signal portions 511a, 511b, via the positive and negative output terminals 508a, 508b, respectively. In some examples, the positive input signal portion 504a can be 180 degrees out of phase with respect to negative input signal portion 504b, and the positive output signal portion 511a can be 180 degrees out of phase with respect to negative output signal portion 511b. In some examples, the windings of the primary and secondary coils 517, 518, may be configured such that the positive input signal portion 504a is in phase with respect to positive output signal portion 511a, and the negative input signal portion 504b is in phase with respect to negative output signal portion 511b. In some embodiments, the primary coil 517 of the balbal transformer 500 may comprise a center tap 506 configured to receive a supply voltage, e.g., from a DC voltage source and provide the DC supply voltage to a device connected to the first positive and negative input terminals 503a, 503b, via the first positive and negative input terminals 503a, 503b.

FIG. 5B is a schematic diagram of a balun transformer 502 configured to receive a differential signal comprising positive and a negative input signal portions 512a, 512b, and output a single ended signal 513. In some embodiments, the balun transformer 502 may comprise a primary coil 519 connecting a positive input terminal 514a to a negative input terminal 514b, magnetically coupled to a secondary coil 520 connecting a signal output terminal 510 to a reference output terminal 515. In some cases, the positive and negative input terminals 514a, 514b, may be configured to receive the positive and a negative input signal portions 512a, 512b, respectively. Additionally, in some cases, the primary and secondary coils 417, 418, can be capacitively coupled by parasitic capacitors 515a, 515b. In some embodiments, the winding of the primary and secondary coils 519, 520, may be configured such that a secondary signal generated between two ends of the secondary coil by a primary signal applied between the two ends of the primary coil is substantially in phase with the primary signal. In some embodiments, the primary coil 519 of the balun transformer 502 may comprise a center tap 522 connected to electric ground.

In various implementations, the turn ratio of the primary and secondary coils 517, 518 (the transformer ratio of the balbal transformer), or the primary and secondary coils 519, 520 (the transformer ratio of the balun transformer), can be 1/N, 1, or N/1, where N is a positive integer. In various implementations, the turn ratio of the primary and secondary coils 517, 518, or the primary and secondary coils 519, 520 can be 1/N, 1, or N/1, where N is a positive integer. In some cases, the turn ratios (herein referred to as transformer ratios) of the balbal and balun transformers may determine the ratio between output and input impedances of the respective transformer.

FIG. 5C is a schematic diagram of an RF system 530 comprising a multi-stage balun transformer 532 (also referred to as multi-stage balun transformer) having a pair of balanced input terminals T1, T2 configured to receive a differential signal from a balanced circuit or device 531, and a pair of unbalanced output terminals T3, T5 configured to output a single ended signal in response to receiving the differential signal by the pair input terminals T1, T2. In some embodiments, the multi-stage balun transformer 532 may comprise a bias terminal T4 configured to receive a supply voltage Vcc, e.g., from a voltage source. In some such embodiments, the multi-stage balun transformer 532 may be configured to provide the supply voltage Vcc to the device or circuit 531 via the pair of input terminals. In some examples, the pair of input terminals may comprise the positive input terminal, T1, configured to receive a positive signal portion of the differential signal (provided by the device or circuit 531), and the negative input terminal, T2, configured to receive a negative signal portion of the differential signal. In some cases, the positive input terminal T1 may be connected to a positive differential output terminal DTp of the device or circuit 531 and the negative input terminal T2 may be connected to a negative differential output terminal DTn of the device or circuit 531. In some examples, the pair of output terminals may comprise a reference output terminal T5 and a signal output terminal, T3, configured to output the single ended signal with respect to the reference terminal T5. In some examples, the reference output terminal T5 may be connected to the electric ground and the signal output terminal T3 may be connected to a device (e.g., antenna) having a resistance R. In various implementations, R can be from 10 to 30 ohms, from 30 to 50 ohms, from 50 to 75 ohms, from 75 ohms to 100 ohms, or any ranges formed by these values or larger or smaller values.

Advantageously, in contrast to the single-stage balun transformer 402, the impedances of the positive and negative input terminals T1, T2, of the multi-stage balun transformer 532 can be substantially equal. As such, the amplitudes of the positive and negative signal portions of the differential signal provided to the input terminals T1, T2, can be substantially equal resulting in high level of common noise cancellation, low amplitude of the residual AC signal at the biasing terminal T4, and stability of the supply voltage provided to the circuit or device 531.

In some embodiments, the impedances of the positive and negative input terminals T1, T2 (Z_{in,1}) may be configured to match the output impedances (Z_{out1,p}, Z_{out1,n}) of the respective positive and negative differential output terminals DTp, DTn, and the output impedance (Zₒᵤₜ₂) of the pair of unbalanced output terminals T3, T5, may be configured to match the input impedance (Zᵢₙ₂) of an unbalanced device or circuit that receives the single ended signal provided by the multi-stage balun transformer 532.

In some embodiments, the multi-stage balun transformer 532 may be formed using the balbal transformer 500 and balun transformer 502 described above and by connecting the positive and negative output terminals 508a, 508b, of the balbal transformer 500 to the positive and negative input terminals 514a, 514b, of the balun transformer 502 such that the positive input signal portion 512a comprises the positive output signal portion 511a and the negative input signal portion 512b comprises the negative output signal portion 511b. In some such embodiments, the positive and negative output terminals 508a, 508b, of the balbal transformer 500 may be referred to as intermediate output terminals, the positive and negative output signal portions 511a, 511b, may be collectively referred to as an intermediate output differential signal, and the positive and negative input terminals 514a, 514b, of the balun transformer 502 may be referred to as intermediate input terminals. In some examples, the intermediate output terminals can be balanced.

In some embodiments, the positive input terminal 503a may serve as the positive input terminal T1, the negative input terminal 503b may serve as the negative input terminal T2, the signal output terminal 510 may serve as the signal output terminal T3 and the reference output terminal 515 may serve as reference output terminal T5 of the multi-stage balun transformer 532. In some cases, the biasing terminal T4 of the multi-stage balun transformer 532 can be connected to the center tap 506 of the primary coil 517 of the balbal transformer 500. In some cases, the device or circuit 531 may comprise a differential amplifier.

In some cases, the input differential signal provided to the input terminals T1, T2, can be in phase with the intermediate output differential signal provided to the intermediate input terminals of balun transformer 502. In some embodiments, the intermediate output differential signal can be in phase with the single ended signal output from the signal output terminal T3. In some embodiments, the balbal transformer 500 and balun transformer 502 of the multi-stage balun transformer 532 can both have a transformer ratio of 1. In some embodiments, the balbal transformer 500 and balun transformer 502 of the multi-stage balun transformer 532 can have a transformer ratio of 1 and 1/N, respectively, where N is a positive integer. In some examples, the balun transformer 502 of the multi-stage balun transformer 532 can have a transformer ratio of 1:2. In some embodiments, the RF system 530 shown in FIG. 5C can be a subsystem of a radio frequency front where the circuit or device 531 is a differential amplifier that provides an amplified differential signal to the multi-stage balun transformer 532, and the multi-stage balun transformer 532 covert the amplified single ended signal and provides it to an antenna that generates a corresponding electromagnetic wave propagating in free space.

In some embodiments, the turn or transformer ratio of the balbal transformer 500 may be configured to match the input impedances of T1, T2 (Z_{in,1}) to the output impedances (Z_{out,1}) of DTp, DTn, and to match the output impedance (Zₒᵤₜ₃) of the balbal transformer 500 to the input impedance (Zᵢₙ₃) of the balun transformer 502. In some embodiments, the turn or transformer ratio of the balun transformer 502 may be configured to match the input impedance (Zᵢₙ₃) of the balun transformer 502 to the output impedance (Zₒᵤₜ₃) of the balbal transformer 500, and to match the output impedance (Zₒᵤₜ₂) of the balun transformer 502 to the input impedance of the unbalanced device or circuit that receives the single ended signal provided by the balun transformer 502.

It should be understood the that the multi-stage balun transformer 532 described above, which uses magnetically coupled coils, is an example implementation of multi-stage balun comprising balbal and balun transformers and any configuration comprising distributed elements, conductive lines, lumped elements, or a combination thereof that can be described by an equivalent circuit comprising the multi-stage balun transformer 532 may serve as a multi-stage balun transformer and is within the scope of this disclosure. In various implementations, at least a first portion of a multi-stage balun (e.g., the balbal transformer 500) may be formed using planar circuit elements (e.g., conductive lines formed on or within a substrate) and a second portion of the multi-stage balun (e.g., balun transformer 502) may be formed using lumped elements (e.g., inductors and capacitors mounted on and connected via a circuit board). In some cases, a multi-stage balun may be formed entirely based on planar circuit elements or entirely based on lumped circuit elements.

### Planar Multi-Stage Baluns

In some embodiments, a multi-stage balun may be implemented based on a layered planar structure configured to provide an electromagnetic functionality identical, equivalent, or substantially similar to those of the multi-stage balun transformer 532 described above. In some embodiments, a planar multi-stage balun may comprise an arrangement of conductive lines (e.g., strip lines, microstrip lines, coplanar lines, and the like) and dielectric layers that may be configured to receive a differential signal from a pair of balanced input terminals T1, T2, provide a corresponding single ended signal via a pair of unbalanced output terminals T3, T5, and, in some cases, provide a supply voltage, received via a biasing terminal T4, to a device connected to the balanced input terminals T1, T2. Advantageously, similar to multi-stage balun transformer 532, the pair of balanced input terminals T1, T2, of the planar multi-stage balun may provide substantially identical input impedances resulting in substantially equal amplitudes of positive and negative signal portions of the differential signal thereby high level of common noise cancelation and stability of the supply voltage provided to the device. In some implementations, the conductive lines of one or both balbal and balun transformers of a multi-stage balun transformer may comprise multilayer Low Temperature Co-fired Ceramic (LTCC) components fabricated using a ceramic-based substrate. In some cases, LTCC transformers may use coupled conductive lines configured to provide impedance transformation and signal conversion from balanced to single-ended. In some cases, coupled conductive lines may comprise capacitive coupling. Advantageously, using LTCC transformers may operate at higher frequencies compared to ferromagnetic transformers, and may allow fabrication of smaller and more rugged balun transformers.

In some implementations, the conductive lines of one or both balbal and balun transformers of a multi-stage balun transformer may comprise, Monolithic microwave integrated circuit (MMIC) components made using layered substrates with planar metallization. Advantageously, using MMIC transformer may operate at higher frequencies and provide thermal stability. In some cases, MMIC transformers may comprise gallium arsenide (GaAs) and can be fabricated using integrated passive device (IPD) process.

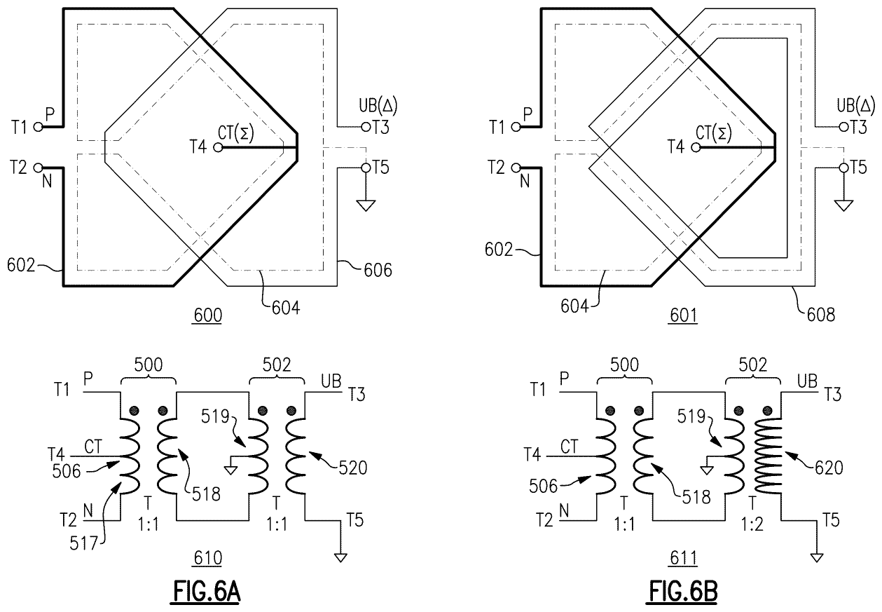

FIG. 6A is a schematic diagram illustrating an example multi-stage balun configuration 600 (top panel) that can be used to implement a planar multi-stage balun transformer comprising balbal and balun transformers having transformer ratios of 1:1, and the corresponding inductor-based equivalent circuit 610 (bottom panel). In some embodiments, the multi-stage balun configuration 600 may comprise an input conductive line 602 connecting a positive input terminal T1 to a negative input terminal T2 and bordering an input region, an output conductive line 606 connecting a signal output terminal T3 to a reference output terminal T5 and bordering an output region, and a closed conductive loop 604 comprising a first portion bordering a first region and a second portion bordering a second region different from the first region. In some cases, the input, output, first, and second regions can be planar regions. In some cases, at least one of the input, output, first, and second regions can be a planar region within a first plane separated in a vertical direction from the one or more planes within which the remaining regions are formed, where the vertical direction is substantially perpendicular to the first plane. In some such cases, the first plane and the one or more planes can substantially parallel with respect to each other and orthogonal to the vertical direction. In some cases, the input, output, first, and second regions can be planar regions within four vertically separated and substantially parallel planes.

In some examples, the input and output regions can partially overlap. In some examples, the first and second regions can partially overlap. In some examples, the input region and the first region can at least partially overlap. In some examples, the output region and the second region can at least partially overlap. It should be understood that the input, output conductive lines 602, 606, and the closed conductive loop are electrically isolated (e.g., by a gap, dielectric layer, or the like) and electric current cannot flow between the input conductive line 602 and the output conductive line 606, between the input conductive line 602 and the closed conductive loop 604, or the output conductive line 606, between the output conductive line 606 and the closed conductive loop 604. In some examples, an overlap between two or more regions bordered and/or enclosed by the conductive lines corresponds to overlap between the projections of corresponding regions on a plane parallel to the plane of the regions.

In some embodiments, the input conductive line 602 can be electromagnetically coupled to the first portion of the closed conductive loop 604 and the output conductive line 606 can be electromagnetically coupled to the second portion of the closed conductive loop 604. As such, the closed conductive loop 604 can electromagnetically couple the input and output conductive lines 602, 606 and thereby the pair of input terminals T1, T2 to the pair of output terminals T3, T5. In various implementations, electromagnetic coupling may comprise capacitive coupling, magnetic coupling, or a combination thereof. It should be understood that in this context, electromagnetic coupling between two lines may comprise captively or magnetically inducing current but does not involve direct current flow between the two conductive lines.

In some embodiments, at least a section of the input conductive line 602 can be substantially parallel to the first portion of the closed conductive loop 604 and at least a section of the output conductive line 606 can be substantially parallel to the second portion of the closed conductive loop 604. In some embodiments, at least a section of the input conductive line 602 can be substantially orthogonal to the output conductive line 606 and at least a section of the first portion of the closed conductive loop can be substantially orthogonal to the second portion of the closed conductive loop 604. In some cases, the input and output conductive lines 602, 604, may be configured to reduce electromagnetic coupling between the pair of input terminals T1, T2, and the pair of output terminals T3, T5, in the absence of the closed conductive loop 604. In some embodiments, the closed conductive loop 604 can be connected to the reference output terminal T5 (e.g., via a middle point of the second portion of the closed conductive loop.

In some embodiments, the input conductive line 602 may be connected to a biasing terminal T4 (e.g., via a middle point of the input conductive line 602) and configured to provide a supply voltage received via the biasing terminal T4 to the pair of input terminals T1, T2, and thereby to a device or circuit that is connected to the pair of input terminals T1, T2.

The bottom panel in FIG. 6A, illustrates the inductor-based equivalent circuit 610 for the multi-stage balun configuration 600 described above. In some cases, the equivalent circuit 610 may comprise one or more features described above with respect to the multi-stage balun transformer 532. In some embodiments, the input and output conductive lines 602, 606, of the multi-stage balun configuration 600 may serve as the primary coil 517 of the balbal transformer 500 and the secondary coil 520 of balun transformer 502, respectively. In some embodiments, the first and second portions of the closed conductive loop 604 of the multi-stage balun configuration 600 may serve as the secondary coil 518 of the balbal transformer 500 and the primary secondary coil 519 of the balun transformer 502, respectively. Accordingly, the pair of input terminals T1, T2, the biasing terminal T4, and the pair of output terminals T3, T5, of the multi-stage balun configuration 600 may serve as the respective terminals of the multi-stage balun transformer 532 and provide similar to identical functionalities. In some embodiments, the balbal transformer 500 and the balun transformer 502 of the equivalent circuit 610 may both have a transformer ratio of 1:1 indicating that the coupling between the input conductive line and output conductive line via the closed conductive loop does not provide voltage gain or current reduction.

FIG. 6B illustrates is a schematic diagram illustrating another example multi-stage balun configuration 601 (top panel) that can be used to implement a planar multi-stage balun transformer comprising balbal and balun transformers having transformer ratios of 1:1 and 1:2, respectively, and the corresponding inductor-based equivalent circuit 611 (bottom panel). In some embodiments, the multi-stage balun configuration 601 and the equivalent circuit 611 may comprise one or more features described above with respect to the multi-stage balun configuration 600 and the equivalent circuit 610. However, in contrast to multi-stage balun configuration 600 and the equivalent circuit 610, the equivalent circuit 611 has a transformer ratio of 1:2 and the output conductive line 608 of the multi-stage balun configuration 601 is configured to provide a voltage gain of 2 from the closed conductive loop 604 to the pair of the output terminals T3, T5, of the multi-stage balun configuration 601 (thereby providing a voltage gain of 2 from the pair of input terminals T1, T2 to the pair of the output terminals T3, T5). In some examples, the output conductive line 608 may comprise two conductive line sections bordering first and second output regions, respectively, where the first and second output regions are at least partially overlapping. In some such examples, at least a portion of each of the two conductive line sections can be substantially orthogonal to a portion of the input conductive line 602. In some such examples, at least a portion of each of the first and second output regions can be substantially parallel to the second portion of the closed conductive loop 604. In some examples, the output conductive line 608 of the multi-stage balun configuration 601 may comprise two interconnected sections (e.g., co-planar sections) having substantially same shapes to provide a transformed ratio of 1:2 when coupled to the second portion of the closed conductive loop formed 604 of the multi-stage balun configuration 601. As such, in these examples, the balbal transformer 500 and the balun transformer 502 of the equivalent circuit 611 may have transformer ratios of 1:1 and 1:2, respectively, indicating that the coupling between the input conductive line and output conductive line via the closed conductive loop provides a voltage gain or current reduction with a factor of 2.

In various implementations, the input region bordered by the input conductive line 602, output conductive region bordered by the output conductive line 606, and the first and second regions enclosed by the closed conductive loop 604 may comprise same or different shapes including a triangular shape, a circular shape, a square, an oval shape, or other shapes. In the embodiments shown in FIGS. 6A and 6B, the input region, output region, first region and second region, can be planar regions and comprise triangular shapes within the same plane or parallel planes. In this embodiment, the input, output, first, and second regions may comprise substantially the same triangular shape and area, however the triangular shapes of the second and output regions may be rotated (e.g., by 180 degrees) with respect to the triangular shapes of the input and first regions, in the respective plane or planes. In the embodiments shown in 6B, the output conductive line 608, may comprise two triangular shapes each bordered by a section of the output conductive line 608 within the same plane or parallel planes.

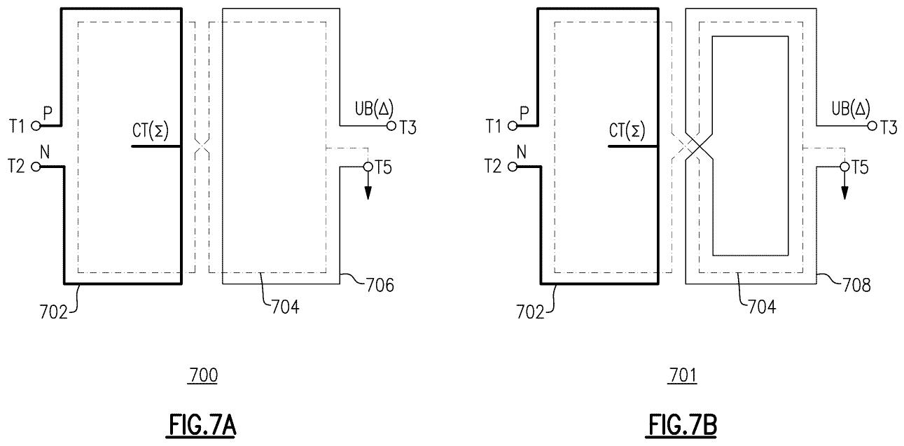

FIG. 7A illustrates is a schematic diagram illustrating another example multi-stage balun configuration 700 that can be implemented as a planar multi-stage balun transformer comprising balbal and balun transformers having transformer ratios of 1:1. The multi-stage balun configuration 700 may comprise one or more features described above with respect to the multi-stage balun configuration 600 and its equivalent circuit 610. In this example, the input conductive line 702 and output conductive line 706 border non-overlapping input and output regions comprising rectangular shapes, and the closed conductive loop 704 comprises first and second portions enclosing first and second regions each comprising a rectangular shape. In some cases, the input, output, first and second regions can be are all planar regions within the same or parallel planes. In some cases, the first and second regions enclosed by the closed conductive loop 704 can be at least partially overlapping with the first and second regions, respectively.

FIG. 7B illustrates is a schematic diagram illustrating another example multi-stage balun configuration 701 that can be implemented as a planar multi-stage balun transformer comprising balbal and balun transformers having transformer ratios of 1:1 and 1:2, respectively. The multi-stage balun configuration 701 may comprise one or more features described above with respect to the multi-stage balun configuration 601 and its equivalent circuit 611. In this example, the input conductive line 702 borders an input region comprising a rectangular shape and the closed conductive loop 704 comprises first and second portions enclosing first and second regions each comprising a rectangular shape. In some cases, the output conductive line 708 of the multi-stage balun configuration 701, may comprise two sections bordering first and second output regions each comprising a rectangular shape. In some cases, the first and second output regions can at least partially overlap with each other and with the second region enclosed by second portion of the closed conductive loop 704. In some examples, the output conductive line 708 of the multi-stage transformer configuration 701 may comprise two interconnected sections (e.g., co-planar sections) having substantially same shapes to provide a transformed ratio of 1:2 when coupled to the second portion of the closed conductive loop formed 704 of the multi-stage transformer configuration 701.

In some cases, the input, output, first and second regions can be planar regions within the same or parallel planes. In some cases, the first and second regions enclosed by the closed conductive loop 704 can be at least partially overlapping with the first and second regions, respectively. Similar to the multi-stage balun configuration 600, 601, described above, the input conductive line 702, the output conductive line 706, and the closed conductive loop 704, are not in electrical contact and overlap between two or more regions bordered and/or enclosed by these conductive lines may indicate overlap between the projections of corresponding regions on a plane parallel to the plane of the regions.

In some embodiments, when implementing a multi-stage balun transformer based on a planar structure, in order to improve electromagnetic coupling between the closed conductive loop (604 or 704) with the input conductive line (602 or 702) and/or the output conductive line (606, 706, 608, or 708), one or both the first and second portions of the closed conductive loop (604 or 704) may be divided into two sections (e.g., two vertically separated sections) connected in parallel and each separately electromagnetically coupled to the input conductive line (602 or 702) or the output conductive line (606, 706, 608, or 708).

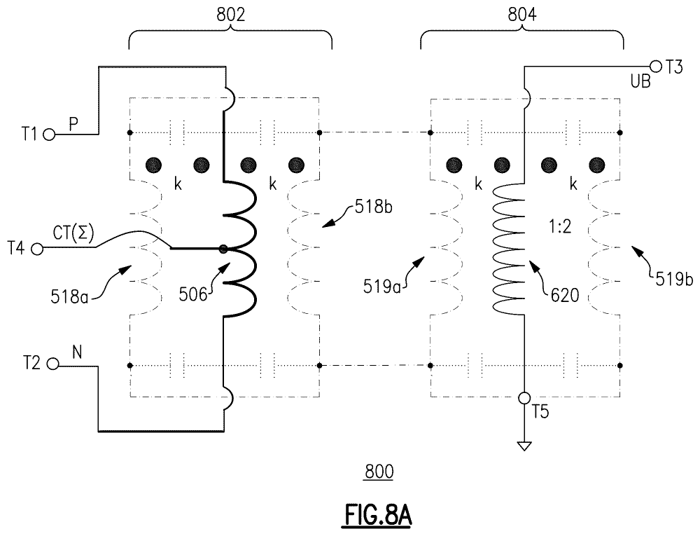

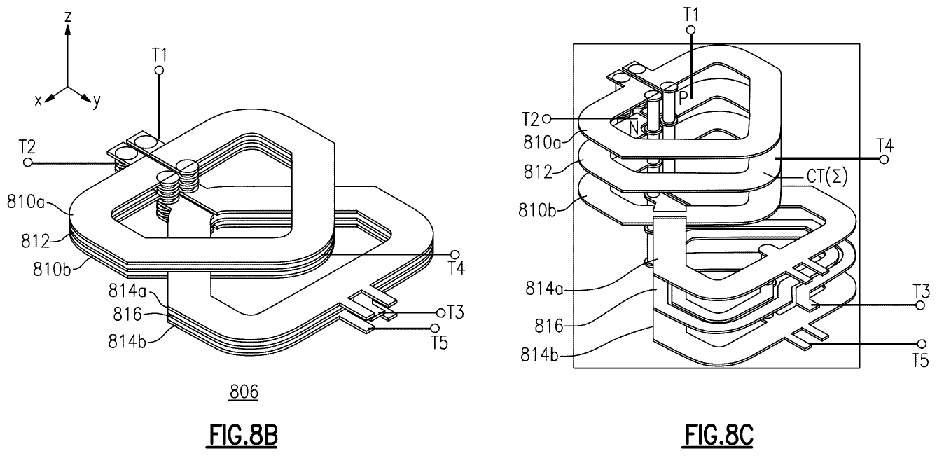

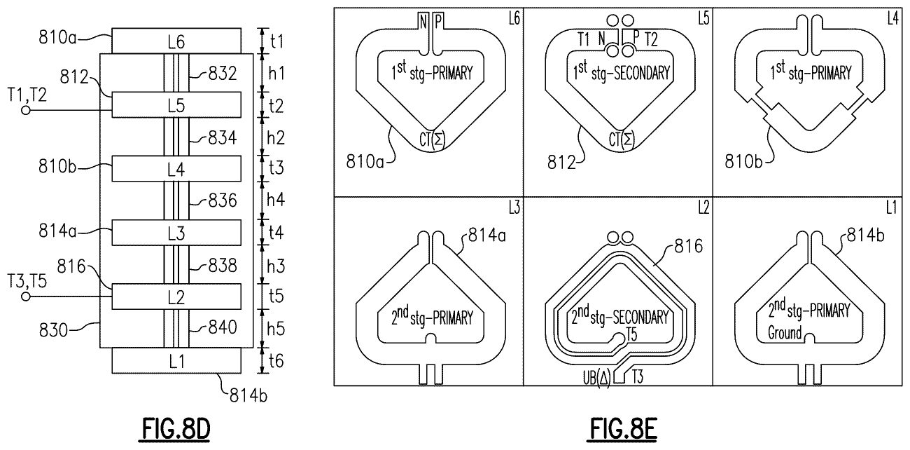

FIG. 8A illustrates a schematic diagram of an example multi-stage balun transformer 800 comprising a modified balbal transformer 802 connected to a modified balun transformer 804. In some embodiments, the multi-stage balun transformer 800 may comprise one or more features described above with respect to multi-stage balun transformer 532. In some embodiments, the modified balbal transformer 802 may comprise two secondary coils 518a, 518b connected in parallel, and the modified balun transformer 804 may comprise two primary coils 519a, 519b, connected in parallel. Advantageously, dividing the secondary coil of the modified balbal and balun transformers 802, 804 into two separate coils may improve the coupling between the secondary and primary coils of the modified balbal and balun transformers 802, 804. Such improved coupling between the secondary and primary coils of the modified balbal and balun transformers 802, 804, can be particularly useful when the multi-stage balun transformer 800 is implemented as a planar multi-stage balun transformer, e.g., based on conductive lines fabricated within a multilayer circuit. In some examples, the planar multi-stage balun transformer may comprise planar conductive lines separated by dielectric layers.

FIGS. 8B-8C schematically illustrate three-dimensional (3D) view of an example a multiplayer multi-stage balun transformer 806 configured based on the multi-stage balun transformer 800 design/configuration shown in FIG. 8A. In FIG. 8C the vertical distances between conductive lines is exaggerated to illustrate the individual transmission lines (e.g., planar transmission lines) and the conductive vias connecting some of the conductive lines.

In some embodiments, the planar multi-stage transformer 806 may comprise an input conductive line 812, an output conductive line 816, and a closed conductive loop that couples the input conductive line 812 to the output conductive line 816. In some examples, the input conductive line 812, the output conductive line 816, and the closed conductive loop can be vertically separated. In some examples, one or more of the input conductive line 812, the output conductive line 816, and the closed conductive loop can be planar conductive lines.

In some embodiments, the closed conductive loop may comprise a first portion and a second portion vertically separated from the first portion (e.g., along z-axis) and electrically connected to the first portion via at least a pair of conductive vias. In some embodiments, the first portion of the closed conductive loop may comprise at least a first planar conductive line 810a and the second portion of the closed conductive loop may comprise at least a second planar conductive line 814a.

In some embodiments, the input planar conductive line 812 can be vertically separated from the first planar conductive line 810a and may electrically connect a pair of input terminals T1, T2 configured to receive an input differential signal.

In some embodiments, the output planar conductive line 816 can be vertically separated from the second planar conductive line 814a and electrically connect a pair of output terminals T3, T5, configured to provide a single ended signal in response to reception of the input differential signal by the pair of input terminals T1, T2. In some cases, the output terminals T3, T5, can be unbalanced. In some examples, the input differential signal and the single ended signal can be substantially in phase.

In some cases, the first planar conductive line 810a, the second planar conductive line 814a, the input planar conductive line 812, and the output planar conductive line 816, can be vertically separated from each other. In some such cases, the first planar conductive line 810a may be formed in a layer above the second planar conductive line 814a, the input planar conductive line 812 may be formed in a layer vertically between the first planar conductive line 810a and the second planar conductive line 814a, and the output planar conductive line 816 may be formed in a layer below the second planar conductive line 814a. In some examples, the first planar conductive line 810a may be vertically separated from the input planar conductive line 812 by a first dielectric layer, the second planar conductive line 814a may be vertically separated from the input planar conductive line 812 by at least a second dielectric layer, and the output planar conductive line 816 may be vertically separated from the second planar conductive line 814a by a third dielectric layer.

In some embodiments, first planar conductive line 810a can be electromagnetically coupled to the input planar conductive line 812, the second planar conducive line 814a can be electromagnetically coupled to the output planar conductive line 816, and the closed conductive loop formed by first and second conductive lines 810a, 814a, may be configured to couple the input planar conductive line 812 to the output conductive line 816.

In some embodiments, the first portion of the closed conductive loop of the planar multi-stage transformer 806 may further comprise a third planar conductive line 810b vertically separated from the first planar conductive line 810a and the input planar conductive line 812, where the third planar conductive line 810b is connected to the first planar conductive line 810a by a second pair of conducive vias and is electromagnetically coupled to the input planar conductive line 812. In some examples, the third planar conductive line 810b may be formed below the input conductive line 812 and above the second conductive line 814a. In some such examples, third planar conductive line 810b may be vertically separated from the input conductive line 812 by the second dielectric layer and from the second conductive line 814a by a fourth dielectric layer.

In some embodiments, the second portion of the closed conductive loop of the planar multi-stage transformer 806 may further comprise a fourth planar conductive line 814b vertically separated from the second planar conductive line 814a and the output planar conductive line 816, where the fourth planar conductive line 814b is connected to the second planar conductive line 814a by a third pair of conducive vias and is electromagnetically coupled to the output planar conductive line 816. In some examples, the fourth planar conductive line 814b may be formed below the output conductive line 816. In some such examples, the fourth planar conductive line 814b may be vertically separated from the output conductive line 816 by a fifth dielectric layer.

In some embodiments, at least a portion of the input planar conductive line 812 can be parallel to a portion of the first planar conductive line 810a and a portion of the third planar conductive line 810b.

In some embodiments, at least a portion of the output planar conductive line 816 can be parallel to a portion of the second planar conductive line 814a and a portion of the fourth planar conductive 814b.

In some embodiments, projections of a first region bound by the first planar conductive line 810a and a third region bound by the third planar conductive line 810b on a plane of the input planar conductive line 812 at least partially overlap with an input region bound by the input planar conductive line. In some such embodiments, the first, third, and input regions comprise triangular shapes. In some embodiments, the first, third, and input regions comprise identical shapes and areas. In some such embodiments, projections of the first and third regions on the plane of the input planar conductive line 812, comprise the input region.

In some embodiments, projections of a second region bound by the second planar conductive line 814a and a fourth region bound by the fourth planar conductive line 814b on a plane of the output planar conductive line at least partially overlap with an output region bound by the output planar conductive line 816. In some such embodiments, the second, fourth, and output regions comprise triangular shapes. In some embodiments, the second, fourth, and output regions comprise identical shapes and areas. In some such embodiments, projections of the second and fourth regions on the plane of the output planar conductive line 816 comprise the output region.

In some embodiments, at least a portion of the input planar conductive line 812 can be perpendicular to a portion of the output planar conductive line 816, a portion of the second planar conductive line 814a and a portion of the fourth planar conductive line 814b. In some embodiments, at least a portion of the output planar conductive line 816 can be perpendicular to a portion of the input planar conductive line 812, a portion of the first planar conductive line 810a and a portion of the third planar conductive line 810b.

In some embodiments, the planar multi-stage transformer 806 may further comprise a biasing terminal T4 connected between the input planar conductive line 812 and a DC voltage source. In some such embodiments, the biasing terminal T4 may be connected to a center point of the input planar conductive line 812 such that the electrical paths from the biasing terminal T4 to a positive input terminal T1 and a negative input terminal T2 of the pair of input terminals are substantially identical.

In some embodiments, the input terminals T1, T2 of the planar multi-stage transformer 806 may be connected to a pair of signal terminals of a balanced circuit or device, wherein the signal terminals are configured to provide the input differential signal to the balanced-balanced signal transformer and receive the DC voltage, via the pair of input terminals. In some examples, the device or balanced circuit may comprise a differential amplifier. In some embodiments, the input planar conductive line 812 may be configured to provide a DC voltage received from the DC voltage source via the biasing terminal T4 to the balanced circuit or device via the pair of input terminals T1, T2. In some embodiments, a signal terminal T3 of the pair of output terminals can be connected to a device (e.g., an antenna) and a reference output terminal T5 of the pair of output terminals can be connected to electric ground. In some embodiments, embodiments, the planar multi-stage transformer 806 may be included in a radio frequency (RF) front end of an RF wireless system and configured to transform a differential signal received from a differential amplifier of the RF front end and to provide a corresponding single ended signal an antenna of the RF front end.

FIG. 8D illustrates a side cross-sectional side view of the planar multi-stage balun transformer 806 shown in FIGS. 8B-8C showing the first, second, third, fourth, input, and output, planar conductive lines 810a, 814a, 810b, 814b, 812, and 816 that are vertically separated by different portions of a dielectric layer 830. In some embodiments, the dielectric layer 830 may comprise multiple dielectric sublayers where each dielectric sublayer can be vertically extended between two consecutive planar conductive lines of the planar multi-stage balun transformer 806. In some such embodiments, different dielectric sublayers may comprise different materials having different dielectric properties. In some embodiments, the first and third planar conductive lines 810a, 810b, may be connected by two pairs of vias 832, 834 to form the first portion of the closed conductive loop, and the second and fourth planar conductive lines 814a, 814b, may be connected by two pairs of vias 838, 840 to form the second portion of the closed conductive loop. In some embodiments, the first and second portions of the closed conductive loop may be connected a pair of conductive vias 836 to form the closed conductive loop. In some examples, each pair of the pairs of conductive vias 832, 834, 836, 838, 840, may be extended in a vertical direction within a dielectric sublayer between the respective planar conductive lines connected the corresponding pair of conductive vias.

In some embodiments, the first dielectric sublayer vertically extended between the first and input planar conductive lines 810a, 812, may have thickness h1, the second dielectric sub layer vertically extended between the input and third planar conductive lines 812, 810b, may have thickness h2, the third dielectric sublayer vertically extended between the second and output planar conductive lines 814a, 816, may have thickness h3, the fourth dielectric sublayer vertically extended between the third and second planar conductive lines 810b, 814a, may have thickness h4, and the fifth dielectric layer vertically extended between the output and fourth planar conductive lines 816, 814b, may have thickness h5. In various, implementations, h1, h2, h3, h4, and h5 can be different or substantially equal. In some examples, at least two thickness values of the h1, h2, h3, h4, and h5 can be substantially equal. In some embodiments, any of the thicknesses h1, h2, h3, h4, and h5 can be from 0.1 to 0.3 mm, from 0.3 mm to 0.5 mm, from 0.5 mm to 1 mm, or any ranges formed by these values or larger or smaller values.

In some embodiments, the first, input, third, second, output, and fourth planar conductive lines 810a, 812, 810b, 814a, 816, 814b, may have thicknesses of t1, t2, t3, t4, t5, and t6, respectively. In various implementations, t1, t2, t3, t4, t5, and t6 can be different or substantially equal. In some examples, at least two thickness values of the t1, t2, t3, t4, t5, and t6 can be substantially equal.

In various implementations, the planar conductive lines 810a, 812, 810b, 814a, 816, 814b, may comprise aluminum, copper, gold, or another conductive material or an alloy comprising one or more metals. In some embodiments, any of the dielectric sublayers may be formed by deposition of the sublayer over or on a substrate or an underlying dielectric sublayer and the planar conductive line thereon. In some examples, the dielectric sublayers may be deposited using a dielectric material deposition process (e.g., sputtering, evaporation, epitaxy, and the like) or, in some cases, by laminating a preexisting dielectric layer on the underlying dielectric sublayer and the planar conductive line thereon. In some embodiments, the planar conductive lines 810a, 812, 810b, 814a, 816, 814b, may comprise strip lines formed by metal deposition and photolithographic patterning over the respective sublayers. In some embodiments, the lateral width of a planar conductive line can be from 0.5 to 1 mm, from 1 mm to 2 mm, from 2 mm to 3 mm, or any ranges formed by these values or larger or smaller values.

FIG. 8E illustrates top views of the conductive lines 810a, 812, 810b, 814a, 816, 814b that are stacked and electrically connected to form the planar multi-stage balun transformer shown in FIGS. 8B-8C. As shown in FIG. 8E, the output planar conductive line 816 of the planar multi-stage transformer 806 may comprise two interconnected co-planar sections having substantially same shapes where one section is formed within the other one to provide a transformer ratio of 1:2 when coupled to the second portion of the closed conductive loop formed by one or both the second and fourth conductive lines 814a, 814b.

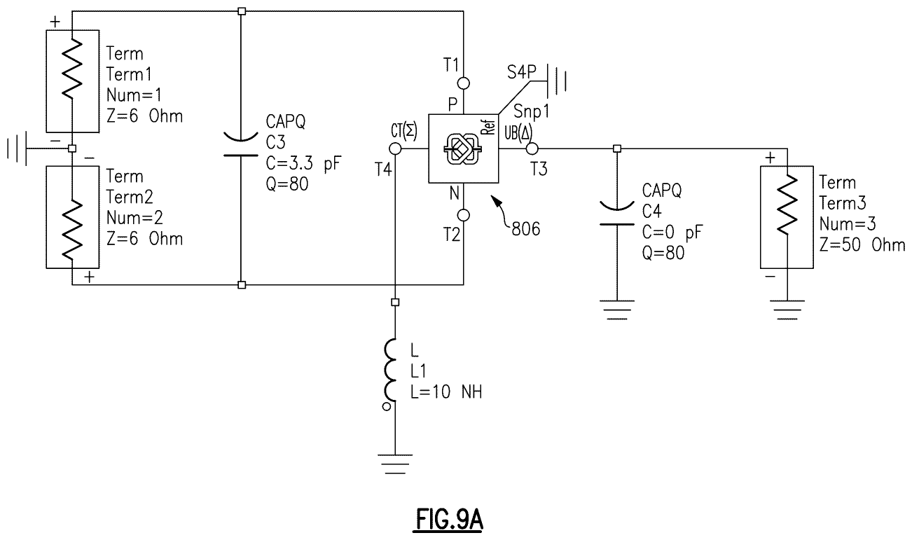

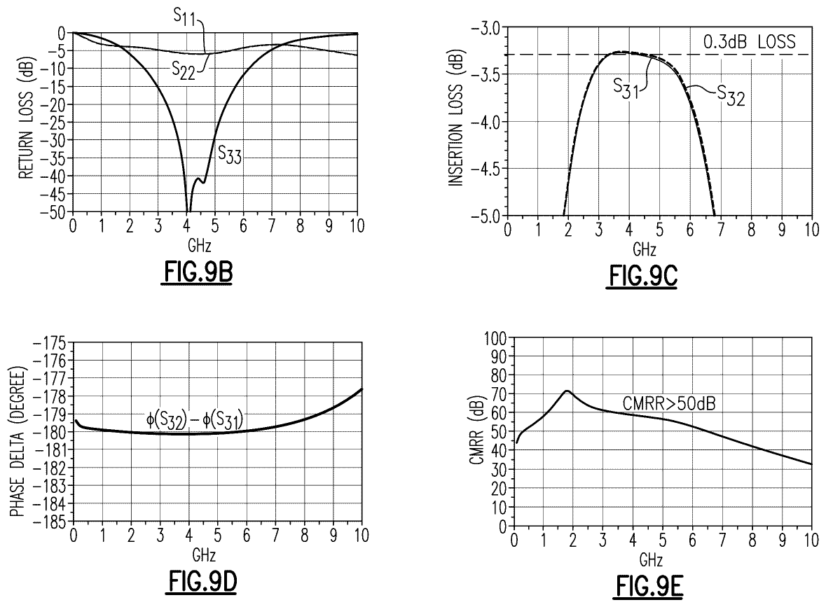

FIG. 9A illustrates the equivalent circuit of an RF system that uses the planar multi-stage balun transformer 806 shown in FIGS. 8B-8E to connect a balanced portion of the RF system to an unbalanced portion of the RF system. In this example, the balanced portion of the RF system is modeled as a differential source having positive and negative signal output terminals, each having an output impedance of 6 ohms, connected to the positive and negative terminals T1, T2, of the planar multi-stage balun transformer 806, respectively. The resulting single ended signal is delivered from the signal output terminal T3 of the planar multi-stage balun transformer 806 to a load having a resistance of 50 ohms.

FIGS. 9B-9E illustrate the spectrum of the calculated return losses (B), insertion losses (C), phase difference between output signals (D), and common mode rejection ratio for the planar multi-stage transformer 806 and based on the equivalent circuit shown in FIG. 9A. Here S22 and S11 are the return losses of the two input terminals T1, T2, S33 is the return loss of the signal output terminal T3, S31 and S32 are the insertion losses from T1 to T3 and from T2 to T3, respectively, φ(S₃₂)−φ(S₃₁) is the phase difference between the single paths formed between T1 and T3, and T2 and T3, respectively, and CMRR is the common mode rejection ratio the planar multi-stage transformer 806. As indicated by these spectrums planar multi-stage transformer 806 can provide an insertion loss of less than- 3.5 dB from 3 to 5 GHz, maintain a φ(S₃₂)−φ(S₃₁) of 180 from 2 to 6 GHz, and provide a CMRR of larger than 50 dB from 0.5 to 6 GHz.

### Hybrid Multi-Stage Baluns

In some embodiments, at least one of the balbal or balun transformer of a multi-stage balun transformer may comprise a circuit implemented based on lumped elements (herein referred to as a lumped element circuit). In some embodiments, one of the balbal or the balbal or balun transformer of a multi-stage balun transformer may comprise a planar circuit and the other one a lumped element circuit. In some embodiments, the lumped element circuit may comprise an inductive transformer having primary and secondary coils, or a lattice balun transformer. In some examples, a lattice balun may comprise a lumped LC-balun formed by a network of interconnected capacitors and inductors configured to transform a differential signal to a single ended signal. In some embodiments, the balun transformer of a multi-stage balun transformer may comprise a lattice balun and the balbal transformer of the of a multi-stage balun transformer may comprise a planar balbal transformer or a lumped element inductive transformer. Advantageously, using the lattice balun as the balun transformer of a multi-stage balun transformer may allow fabricating more compact multi-stage lattice baluns or reduce the fabrication cost and complexity of the multi-stage balun transformer. In some examples, the planar balbal transformer may comprise two electromagnetically coupled conductive lines, e.g., formed in two vertically separated substantially parallel planes.

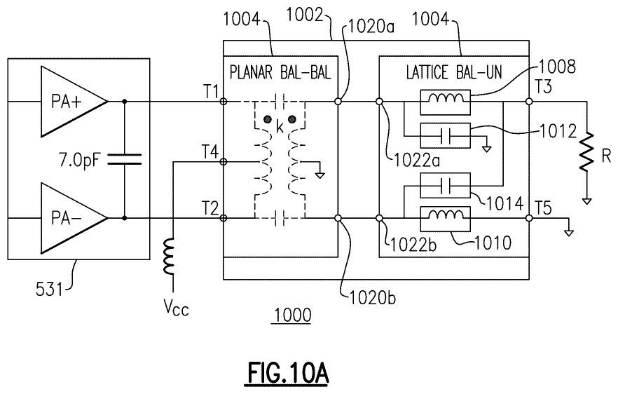

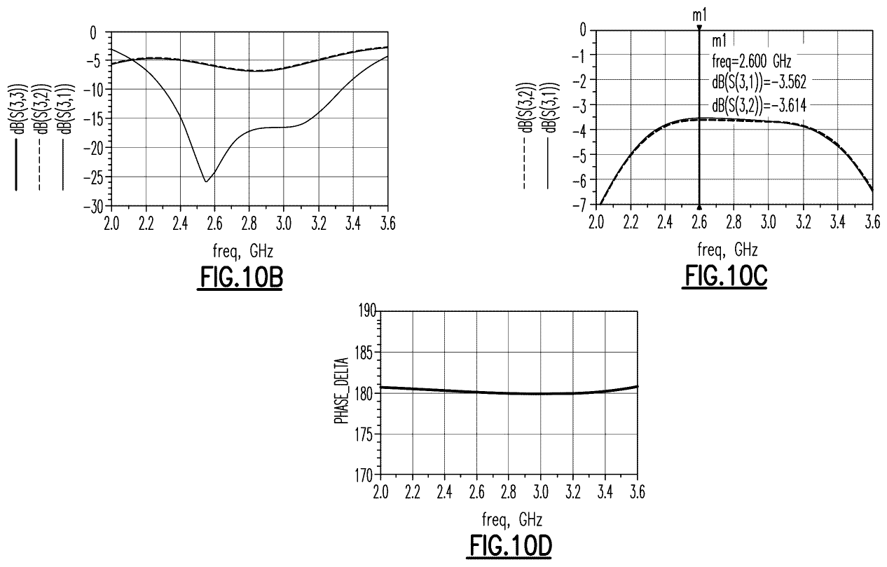

FIG. 10A is a schematic diagram of an RF system 1000 comprising a multi-stage balun transformer 1002 formed using a lattice balun and configured to provide a supply voltage to a circuit or device 531 connected to its input terminals T1, T2. In some embodiments, the multi-stage balun transformer 1002 may comprise one or more features described above with respect to the RF system 530 and the multi-stage balun transformer 532 described above with respect to FIG. 5C. In some embodiment, the multi-stage balun transformer 1002 may comprise a balbal transformer 1004 connected in series with a lattice balun transformer 1006. The balbal transformer 1004 may be configured to receive a differential signal from a pair of input terminals T1, T2, and provide an intermediate output differential signal to the lattice balun transformer 1006 via two intermediate output terminals 1020a, 1020b. The lattice balun transformer 1006 may be configured to output a single ended signal via a pair of output terminals T3, T5, in response to receiving the intermediate output signal from the balbal transformer 1004 via two intermediate input terminals 1022a, 1022b. In various implementations, the balbal transformer 1004 may comprise a lumped element inductive transformer (similar to balbal transformer 500 in the multi-stage balun transformer 532), or a planar balbal transformer formed by planar conductive lines and dielectric layers.

In some embodiments, the lattice balun transformer 1006 may comprise a first inductor 1008 connected between a first intermediate input terminal 1022a of the pair of intermediate input terminals, and a first output terminal (the signal terminal) T3 of the pair of output terminals, a second inductor 1010 connected between a second intermediate input terminal 1022 of the pair of intermediate input terminals and a second output terminal (the ground terminal) T5 of the pair of output terminals, a first capacitor 1012 connected between the first intermediate input terminal 1022a and the second output terminal T5, and a second capacitor 1014 connected between the second intermediate input terminal 1022b and the first output terminal T3.

In some embodiments, the balbal transformer 1004 may comprise a primary coil connected between the pair of input terminals T1, T2, and a secondary coil connected to the pair of intermediate output terminals 1020a, 1020b, wherein the first primary coil is magnetically coupled to the first secondary coil. In some examples, the transformer (or turn) ratio of the balbal transformer can be 1:1. In some examples, primary coil of the balbal transformer 1004 may comprise a center tap connected to dc basing terminal T4 through which the balbal receives a supply voltage (Vcc), e.g., from a DC voltage source. In some such examples, the primary coil may provide the received supply voltage to the device/circuit 531 via the pair of input terminals T1, T2.

FIGS. 10B-10D illustrate the spectrum of the return losses (B), insertion losses (C), phase difference between output signals (D), for the multi-stage balun transformer 1002 shown in FIG. 10A when: the inductances of the first and second inductors 1008, 1010 are 1 nano-Henry transformers and the capacitances of the first and second capacitors 1012, 1014 are 2 pico-Farads, the input and output impedances of the balbal transformer 1004 are 12.5 ohms, the input impedance of the lattice balun transformer 1006 is 12.5 ohm, the output impedance of the lattice balun transformer 1006 is 50 ohm, the insertion loss of the balbal transformer 1004 is 0.2 dB, and the insertion loss of the balun transformer 1006 is 0.35 dB. As shown in FIGS. 10B-10D, the performance of the multi-stage balun transformer 1002 is comparable to that of the planar multi-stage balun transformer 806.

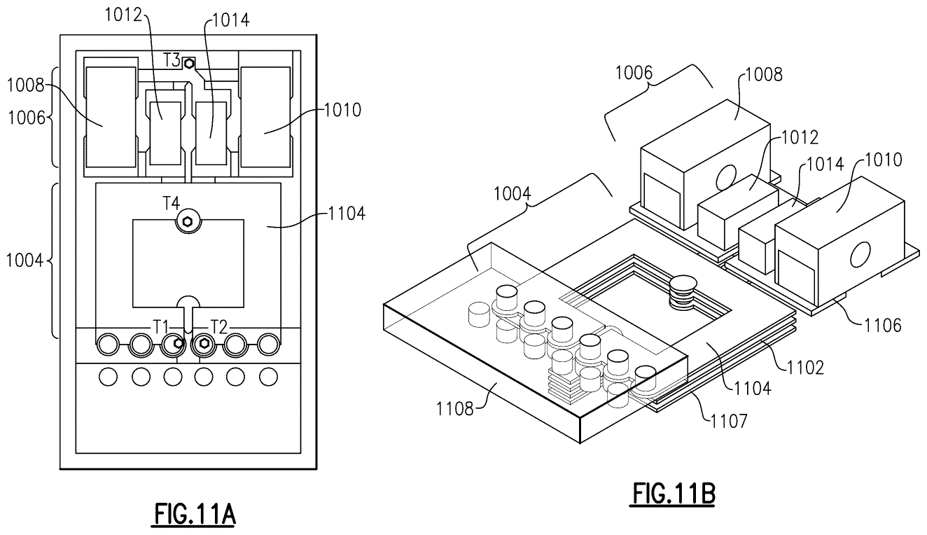

FIGS. 11A-11B illustrate top view (A) and 3D view (B) of an example implementation of the multi-stage balun transformer 1002 shown in FIG. 10A where the balbal transformer 1004 comprises a planar transformer. In some embodiments, the lattice balun transformer 1006 may be fabricated over a first substrate 1106. In some examples, the first substrate 1106 may comprise a printed circuit board (PCB) through which the inductors 1008, 1010, and the capacitors 1012, 1014, of the lattice balun transformer 1006 are connected. In some cases, the inductors 1008, 1010, and the capacitors 1012, 1014, may be mounted on the first substrate 1106 by soldering. In some cases, one or more of the inductors 1008, 1010, and the capacitors 1012, 1014, can be surface mount components.

In some embodiments, the balbal transformer 1004 may comprise a multilayer structure including a first planar conductive line 1102 connecting the pair of intermediate output terminals 1020a, 1020b, and a second planar conductive line 1104 formed above the first conductive line 1102 and connecting the pair of input terminals T1, T2, where the second conductive line 1104 is electromagnetically coupled to the first conductive line 1102 and is vertically separated from the first conductive line 1102 by a dielectric layer (not shown). In some cases, the first and second conductive lines 1102, 1104, and the dielectric layer therebetween may be formed over a second substrate 1107. In some examples, the second substrate 1107 may be separate from the first substrate 1106. In some examples, the second substrate 1107 may comprise the first substrate 1106 (e.g., the balbal transformer 1004 and balun transformer 1006 may be formed over a common substrate). In some embodiments, at least a portion of the first planar conductive line 1102 can be substantially parallel to a portion of the second conductive line 1104. In some examples, a first region bounded by the first conductive line 1102 may comprise a rectangular or square shape. In some such examples, a second region bound by the second conductive line 1104 may comprise a rectangular or square shape. In some cases, the first and second regions may comprise the same shape and areas. In some such cases, a projection of the second region on the plane of the first conductive line 1102 may comprise the first region.

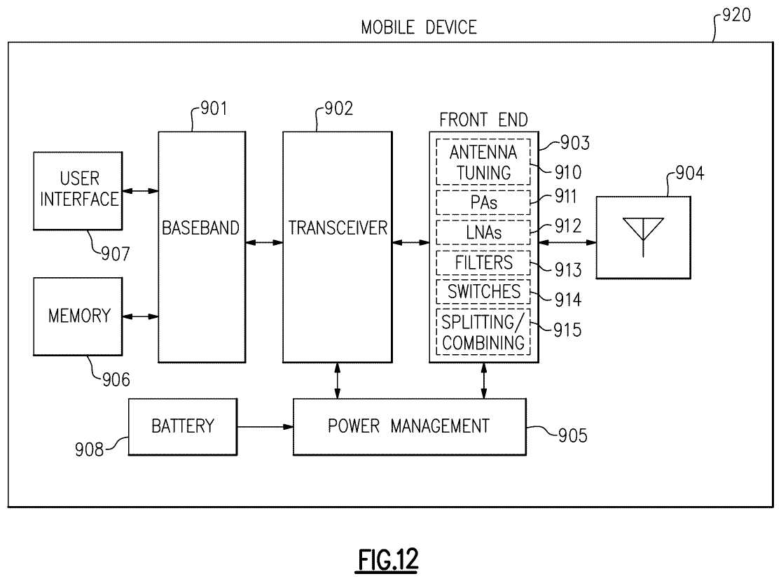

FIG. 12 is a schematic diagram of one embodiment of a mobile device 920. The mobile device 920 includes a baseband system 901, a transceiver 902, a front-end system 903, antennas 904, a power management system 905, a memory 906, a user interface 907, and a battery 908. In some embodiments, the front-end system 903 may comprise a dual-transistor amplifier circuit having one or more features described above. In some embodiments, the front-end system 903 may comprise one of multi-stage balun transformers 532, 600, 601, 700, 701, 800, 806, 1002 described above.

The mobile device 920 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 902 generates RF signals for transmission and processes incoming RF signals received from the antennas 904. It will be understood that various functionalities associated with the transmission and receiving of RF signals can be achieved by one or more components that are collectively represented in FIG. 12 as the transceiver 902. In one example, separate components (for instance, separate circuits or dies) can be provided for handling certain types of RF signals. Such separate transceiver circuits or dies can receive separate RF split signals from the front-end systems implemented in accordance with the teachings herein.

The front-end system 903 aids in conditioning signals transmitted to and/or received from the antennas 904. In the illustrated embodiment, the front-end system 903 includes antenna tuning circuitry 910, power amplifiers (PAs) 911, low noise amplifiers (LNAs) 912, filters 913, switches 914, and signal splitting/combining circuitry 915. The front-end system 903 can be implemented in accordance with any of the embodiments herein.

With continuing reference to FIG. 12, the front-end system 903 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 920 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 904 can include antennas used for a wide variety of types of communications. For example, the antennas 904 can include antennas for transmitting and/or receiving signals associated with a wide variety of frequencies and communications standards.

In certain implementations, the antennas 904 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 920 can operate with beamforming in certain implementations. For example, the front-end system 903 can include amplifiers having controllable gain and phase shifters having controllable phase to provide beam formation and directivity for transmission and/or reception of signals using the antennas 904. For example, in the context of signal transmission, the amplitude and phases of the transmit signals provided to the antennas 904 are controlled such that radiated signals from the antennas 904 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 904 from a particular direction. In certain implementations, the antennas 904 include one or more arrays of antenna elements to enhance beamforming.

The baseband system 901 is coupled to the user interface 907 to facilitate processing of various user input and output (I/O), such as voice and data. The baseband system 901 provides the transceiver 902 with digital representations of transmit signals, which the transceiver 902 processes to generate RF signals for transmission. The baseband system 901 also processes digital representations of received signals provided by the transceiver 902. As shown in FIG. 12, the baseband system 901 is coupled to the memory 906 to facilitate operation of the mobile device 920.

The memory 906 can be used for a wide variety of purposes, such as storing data and/or instructions to facilitate the operation of the mobile device 920 and/or to provide storage of user information.

The power management system 905 provides a number of power management functions of the mobile device 920. In certain implementations, the power management system 905 includes a PA supply control circuit that controls the supply voltages of the power amplifiers 911. For example, the power management system 905 can be configured to change the supply voltage(s) provided to one or more of the power amplifiers 911 to improve efficiency, such as power added efficiency (PAE).

As shown in FIG. 12, the power management system 905 receives a battery voltage from the battery 908. The battery 908 can be any suitable battery for use in the mobile device 920, including, for example, a lithium-ion battery.

### Applications

Some of the embodiments described above have provided examples in connection with mobile devices. However, the principles and advantages of the embodiments can be used for a wide range of RF communication systems. Examples of such RF communication systems include, but are not limited to, mobile phones, tablets, base stations, network access points, customer-premises equipment (CPE), laptops, and wearable electronics.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, where these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A multi-stage transformer comprising:
a balanced-balanced (balbal) transformer including a pair of input terminals configured to receive an input differential signal, and a pair of intermediate output terminals configured to output an intermediate differential signal; and
a balanced-unbalanced (balun) transformer including a pair of intermediate input terminals connected to the pair of intermediate output terminals and configured to receive the intermediate differential signal from the balanced-balanced transformer, and a pair of output terminals configured to output a single ended signal.

2. The multi-stage transformer of claim 1 wherein the balanced-balanced transformer includes a biasing terminal connected to a DC voltage source and the balanced-balanced transformer is configured to provide the DC voltage to a balanced circuit.

3. The multi-stage transformer of claim 2 wherein the input terminals are connected to a pair of signal terminals of the balanced circuit, and the pair of signal terminals are configured to provide the input differential signal to the balanced-balanced transformer and receive the DC voltage, via the pair of input terminals.

4. The multi-stage transformer of claim 1 wherein the output terminals are unbalanced.

5. The multi-stage transformer of claim 1 wherein the intermediate output terminals are balanced.

6. The multi-stage transformer of claim 1 wherein a first output terminal of the pair of output terminals is connected to a device and a second output terminal of the pair of output terminals is connected to electric ground.

7. The multi-stage transformer of claim 1 wherein the transformer ratio of the balanced-balanced transformer is 1:1.

8. The multi-stage transformer of claim 7 wherein the transformer ratio of the balanced-unbalanced transformer is 1:1.

9. The multi-stage transformer of claim 7 wherein the transformer ratio of the balanced-unbalanced transformer is 1:N, where N is an integer larger than 1.

10. The multi-stage transformer of claim 1 wherein the balanced-balanced transformer includes a first primary coil connected between the pair of input terminals and a first secondary coil connected to the pair of intermediate output terminals, wherein the first primary coil is magnetically coupled to the first secondary coil.

11. The multi-stage transformer of claim 10 wherein the first primary coil includes a center tap connected to a voltage source.

12. The multi-stage transformer of claim 1 wherein the balanced-unbalanced transformer includes a second primary coil connected between the pair of intermediate output terminals and a second secondary coil connected to the pair of output terminals, wherein the second primary coil is magnetically coupled to the second secondary coil.

13. The multi-stage transformer of claim 12 wherein the second primary coil includes a center tap connected to electrical ground.

14. The multi-stage transformer of claim 1 wherein the balanced-unbalanced transformer includes a lattice transformer fabricated over a first substrate.

15. The multi-stage transformer of claim 14 wherein the lattice transformer includes:
a first inductor connected between a first intermediate input terminal of the pair of intermediate input terminals and a first output terminal of the pair of output terminals;
a first inductor connected between a second intermediate input terminal of the pair of intermediate input terminals and a second output terminal of the pair of output terminals;
a first capacitor connected between the first intermediate input terminal and electric ground; and
a second capacitor connected between the second intermediate input terminal the first output terminal.

16. The multi-stage transformer of claim 14 wherein the lattice transformer includes a lumped element circuit.

17. The multi-stage transformer of claim 14 wherein the balanced-balanced transformer includes a first primary coil connected between the pair of input terminals and a first secondary coil connected to the pair of intermediate output terminals, wherein the first primary coil is magnetically coupled to the first secondary coil.

18. The multi-stage transformer of claim 14 wherein the balanced-balanced transformer includes a multilayer structure including a first planar conductive line connecting the pair of intermediate output terminals and a second planar conductive line connecting the pair of input terminals, wherein the second planar conductive line is electromagnetically coupled to the first planar conductive line and is vertically separated from the first planar conductive line by a dielectric layer.

19. A radio frequency module comprising:
a differential power amplifier configured to provide an amplified output signal; and
a multi-stage transformer including a balanced-balanced (balbal) transformer, the balanced-balanced transformer including a pair of input terminals configured to receive the amplified output signal, and a pair of intermediate output terminals configured to output an intermediate differential signal; and a balanced-unbalanced (balun) transformer, the balanced-unbalanced transformer including a pair of intermediate input terminals connected to the pair of intermediate output terminals and configured to receive the intermediate differential signal from the balanced-balanced transformer, and a pair of output terminals configured to output a single ended signal.

20. A mobile device comprising:
a differential power amplifier configured to provide an amplified output signal;
a multi-stage transformer including a balanced-balanced (balbal) transformer, the balanced-balanced transformer including a pair of input terminals configured to receive the amplified output signal, and a pair of intermediate output terminals configured to output an intermediate differential signal; and a balanced-unbalanced (balun) transformer, the balanced-unbalanced transformer transformer including a pair of intermediate input terminals connected to the pair of intermediate output terminals and configured to receive the intermediate differential signal from the balanced-balanced transformer, and a pair of output terminals configured to output a single ended signal; and
an antenna arranged to receive the single ended signal and to wirelessly transmit the single ended signal.
